(19) United States
(12) Patent Application Publication
(10) Pub. No.: US 2017/0139219 A1
(43) Pub. Date: May 18, 2017

(54) ARRAY SUBSTRATE, DISPLAY PANEL AND DISPLAY APPARATUS

(71) Applicant: BOE Technology Group Co., Ltd., Beijing (CN)

(72) Inventor: Chia-Chiang Lin, Beijing (CN)

(21) Appl. No.: 15/106,967

(22) PCT Filed: Sep. 21, 2015
(86) PCT No.: PCT/CN2015/090066

§ 371 Date: Jun. 21, 2016

(30) Foreign Application Priority Data
Apr. 13, 2015 (CN) 201510174119.5

(51) Int. Cl. G02B 27/22; H01L 27/12

(52) U.S. Cl. CPC G02B 27/2214; H01L 27/124; H01L 27/1218

(57) ABSTRACT

The present disclosure relates to the field of display technology. Disclosed is an array substrate including: a plurality of gate lines, a plurality of data lines, and an array of pixels defined by intersections of the plurality of gate lines and the plurality of data lines, wherein, pixels in the array of pixels are arranged inclinedly along an inclination direction, making an angle α with a rim of the array substrate, in which the angle α is greater than 0° but is less than 90°, and, being consistent with a rectilinear direction along which the gate lines or the data lines are. The pixel is in a shape of parallelogram, and a rectilinear direction along which a pair of opposite sides of the parallelogram are is consistent with the inclination direction. A display panel and a display apparatus including the abovementioned array substrate are also disclosed.

### BACKGROUND

1. Technical Field

The present disclosure relates to the field of display technology, and particularly to an array substrate, a display panel and a display apparatus.

2. Description of the Related Art

Switchover between a horizontal screen view and a vertical screen view is adopted by mobile phone and flat panel display, etc. consequently a 3D display function should satisfy such requirement. For conventional square pixels, in order to achieve a 3D display in a horizontal screen view or a 3D display in a vertical screen view, as shown in FIG. 1, there is an angle (of 45°, usually) between an arrangement direction of the conventional square pixels and a length direction of a grating (a lens grating or a slit grating). However, because spacings among these pixels are changed when the display is switched over from the horizontal screen view to the vertical screen view (or from the vertical screen view to the horizontal screen view), focal length of lens and height difference between the lens and the pixels are required to be adjusted correspondingly, in order to meet an equal 3D viewing distance. Accordingly, once one 3D display mode (for example, of the horizontal screen view) has a good effect, the other 3D display mode (for example, of the vertical screen view) cannot achieve a good effect of viewing. That is, a 3D display both in a horizontal screen view and a 3D display in a vertical screen view cannot be achieved at the same time.

### SUMMARY

The present disclosure provides an array substrate comprising: a plurality of gate lines, data lines, and an array of pixels defined by intersections of the plurality of gate lines and data lines, wherein, pixels in the array of pixels are arranged inclinedly along an inclination direction that makes an angle α with a rim of the array substrate, in which the angle α is greater than 0° but is less than 90°, and, that is consistent with a rectilinear direction along which the gate lines or the data lines are.

### BRIEF DESCRIPTION OF THE DRAWINGS

FIG. 1 is a schematic view showing a relatively positional relationship among an array of pixels and lenses (or gratings) in a prior art array substrate;

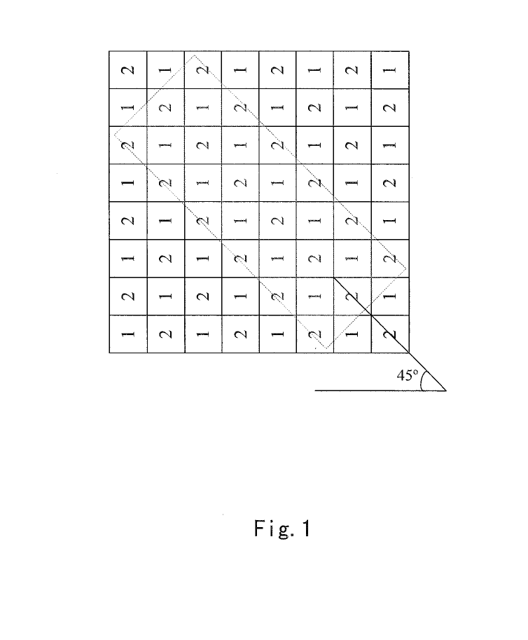

FIG. 2 is a schematic structural view of an array substrate according to an embodiment;

FIG. 3 is a structural view showing a layout deign of these lines between the array substrate of FIG. 2 and a driver; and

FIG. 4 is a schematic view showing another layout deign of these lines between the array substrate of FIG. 2 and a driver.

### DETAILED DESCRIPTION OF THE EMBODIMENTS

Embodiments of the present disclosure will be further described hereinafter in detail in conjunction with examples and with reference to the attached drawings. These embodiments are used for explanation and illustration purposes, but not to limit the present disclosure.

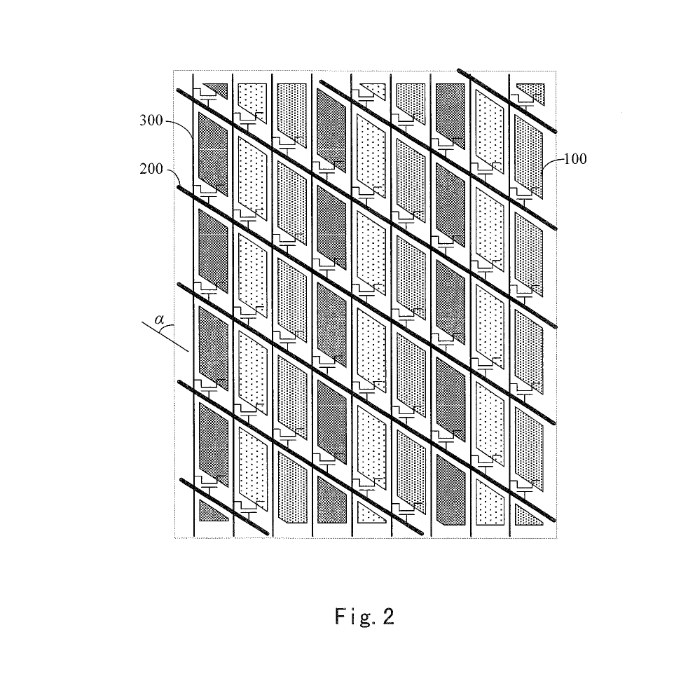

Referring to FIG. 2, an array substrate according to one embodiment of the present disclosure comprises: a plurality of gate lines 200, data lines 300, and an array of pixels defined by intersections of the plurality of gate lines 200 and data lines 300. Usually, in order to achieve a 3D display in a horizontal screen view or a 3D display in a vertical screen view, the grating is designed to make a certain angle (for example, of preferably 45° or close to 45°) with a rim of the array substrate. In order to match a direction of the grating so as to achieve a 3D display both in a horizontal screen view and in a vertical screen view, in this embodiment, pixels 100 in the array of pixels are arranged inclinedly along an inclination direction that makes an angle α with a rim (e.g., a vertical one shown in FIG. 2) of the array substrate, in which the angle α is greater than 0° but is less than 90°. And, the inclination direction is consistent with a rectilinear direction along which the gate lines 200 or the data lines 300 are.

The pixel 100 is in a shape of parallelogram, and a rectilinear direction along which a pair of opposite sides of the parallelogram are is consistent with the inclination direction. Specifically, the inclination direction makes an angle α with a first rim (e.g., a vertical one shown in FIG. 2, while a second rim is a horizontal one shown in FIG. 2) of the array substrate. Ones of the gate lines 200 and the data lines 300 also make an angle α with the first rim, while, the others are parallel to the first rim (but are perpendicular to the second rim). Straight lines along which the pair of opposite sides of the pixel 100 in the shape of parallelogram are also make an angle α with the first rim, while the other pair of opposite sides are parallel to the first rim (but are perpendicular to the second rim).

In the array substrate according to this embodiment, this arrangement of inclination of the pixels makes a direction of arrangement of the pixels to be substantially consistent with a length direction of the grating, so that spacings among the gratings that are required to perform not only a display of the horizontal screen view but also a display of the vertical screen view are substantially equal, achieving a 3D display both in a horizontal screen view and in a vertical screen view.

Moreover, the angle α is close to 45°, for example, α is in a range of 35°˜55°, and preferably, 45°. That is, when a display panel is made, the inclination direction of the pixels 100 is kept to be consistent with a length direction of the lens (or the grating). As a result, an improved 3D display effect is achieved for displaying both in a horizontal screen view and in a vertical screen view.

FIG. 2 shows a situation that a rectilinear direction along which the gate lines 200 are is consistent with the inclination direction. Specifically, the inclination direction makes an angle α with a first rim (e.g., a vertical one shown in FIG. 2) of the array substrate, the gate lines 200 also make an angle α with the first rim, and, the data lines 300 are parallel to the first rim. A pair of opposite sides of the pixel 100 in the shape of parallelogram are also parallel to the gate lines 200, that is, straight lines along which the pair of opposite sides are also make an angle α with the first rim, while the other pair of opposite sides are parallel to the first rim.

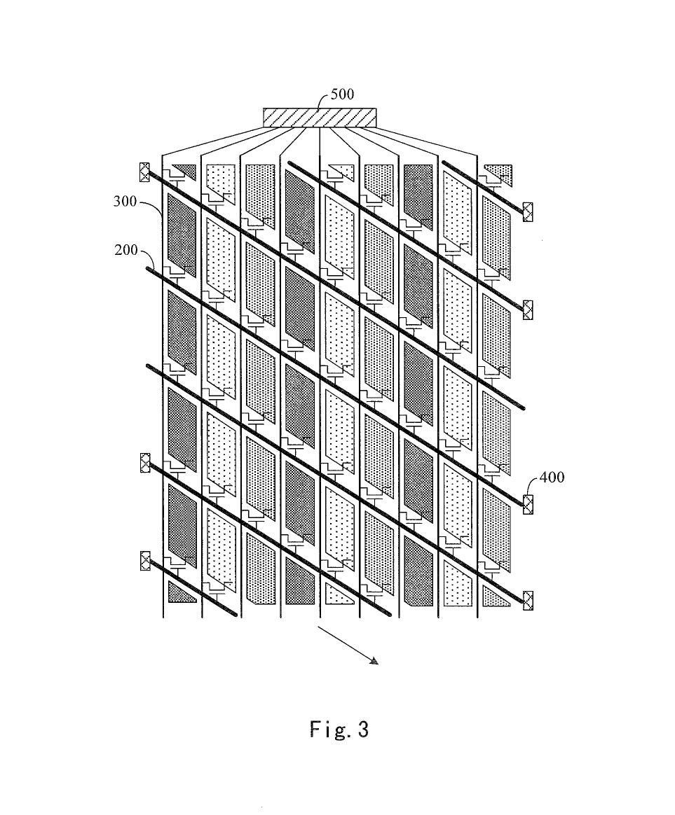

Moreover, the array substrate is a GOA (Gate drive On Array) array substrate in which no gate driver IC is needed, so that a narrowed rim may be obtained. Referring to FIG. 3, for convenience of the wiring, one gate driver 400 is provided at an end of each of the gate lines 200, while all the gate drivers 400 are distributed at both of opposite sides on the array substrate. A source driver IC 500 for the data lines 300 is provided at ends of the data lines and at a side, different from the opposite sides, of the array substrate.

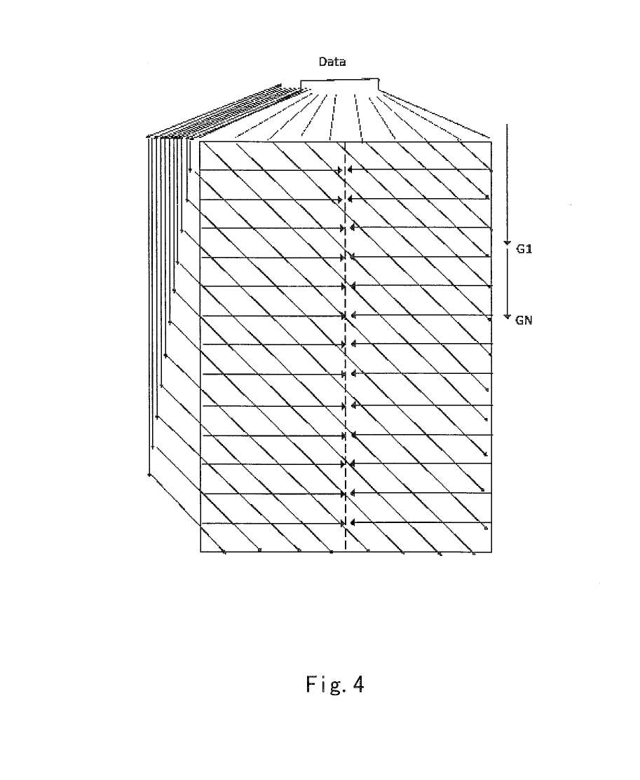

Of course, it may also be that the gate lines are parallel to a rim of the array substrate and the rectilinear direction along which the data lines are is consistent with the inclination direction. Referring to FIG. 4, there will be a wider rim due to the wiring.

The present disclosure also provides a display panel comprising the abovementioned array substrate, namely, a 3D display panel. The 3D display panel comprises the abovementioned array substrate and a grating provided at a side of light emergent surface of the array substrate. The inclination direction of arrangement of the pixels makes an angle β with a length direction of the grating (usually, makes an angle of 45° or near 45° with the rim of the array substrate), in which 0°≦β≦30°. As shown in FIG. 3, the arrow direction denotes the length direction of the grating. FIG. 3 shows a preferred situation in which the inclination direction of arrangement of the pixels makes an angle of 0° with the length direction of the grating but makes an angle of 45° with the rim of the array substrate. Here, the grating may comprise a lens grating and a slit grating.

The present disclosure further provides a display apparatus comprising the abovementioned display panel. The display apparatus preferably comprises mobile equipment including mobile phone, pocket PC, tablet PC and the likes.

These abovementioned embodiments are used for explanation and illustration purposes, but not to limit the present disclosure. And, it would be appreciated by those skilled in the art that various changes or modifications may be made in these embodiments without departing from the principles and spirit of the present disclosure, the scope of which is defined in the claims and their equivalents.

1. An array substrate, comprising: a plurality of gate lines, a plurality of data lines, and an array of pixels defined by intersections of the plurality of gate lines and the plurality of data lines, wherein, pixels in the array of pixels are arranged inclinedly along an inclination direction that makes an angle α with a rim of the array substrate, in which the angle α is greater than 0° but is less than 90°, and that is consistent with a rectilinear direction along which the gate lines or the data lines are.

2. The array substrate of claim 1, wherein, each of the pixels is in a shape of parallelogram, and a rectilinear direction along which a pair of opposite sides of the parallelogram are is consistent with the inclination direction.

3. The array substrate of claim 1, wherein, the angle α is in a range of 35°˜55°.

4. The array substrate of claim 3, wherein, the angle α is 45°.

5. The array substrate of claim 1, wherein, the gate lines are parallel to the rim of the array substrate, and, the rectilinear direction along which the data lines are is consistent with the inclination direction.

6. The array substrate of claim 1, wherein, the data lines are parallel to the rim of the array substrate, and, the rectilinear direction along which the gate lines are is consistent with the inclination direction.

7. The array substrate of claim 6, wherein, the array substrate is a GOA array substrate, one gate driver is provided at an end of each of the gate lines, while all the gate drivers are distributed at both of opposite sides on the array substrate.

8. A display panel, comprising an array substrate of claim 1 and a grating provided at a side of light emergent surface of the array substrate, wherein, the inclination direction makes an angle β with a length direction of the grating, in which 0°≦β≦30°.

9. The display panel of claim 8, wherein, the grating comprises a lens grating and a slit grating.

10. A display apparatus, comprising a display panel of claim.
